(19) United States
(12) Patent Application Publication
(10) Pub. No.: US 2020/0135632 A1
(43) Pub. Date: Apr. 30, 2020

(54) DIE ISOLATION ON A SUBSTRATE

(71) Applicant: Texas Instruments Incorporated, Dallas, TX (US)

(72) Inventors: Dibyajat Mishra, Fremont, CA (US); Vivek Arora, San Jose, CA (US); Ashok Prabhu, San Jose, CA (US); Ken Pham, San Jose, CA (US)

(21) Appl. No.: 16/169,843

(22) Filed: Oct. 24, 2018

(51) Int. Cl. H01L 23/498; H01L 23/00

(52) U.S. Cl. CPC H01L 23/49861; H01L 24/48

(57) ABSTRACT

In a described example, an apparatus includes a substrate with a first surface and an opposing second surface. The substrate includes a trench extending into the substrate from the first surface, a die mounting area adjacent to the trench, a first plurality of leads, and a second plurality of leads. The second plurality of leads are spaced from the trench to electrically isolate the second plurality of leads. The apparatus further includes a first mold compound in the trench forming a filled trench and in the space between the trench and the second plurality of leads. A first die is attached to the first surface of the substrate and a second die is attached to a surface of the first mold compound in the filled trench.

### TECHNICAL FIELD

This application relates generally to electronic circuitry, and more particularly to isolation of electronic devices on a substrate.

### SUMMARY

In a described example, an arrangement includes a substrate with a first surface and an opposing second surface. The substrate includes a trench extending into the substrate from the first surface, a die mounting area adjacent to the trench, a first plurality of leads, and a second plurality of leads. The second plurality of leads are spaced from the die mounting area to electrically isolate the second plurality of leads. A first mold compound fills the trench and is in the space between the trench and the second plurality of leads, a first die is attached to the first surface of the substrate and a second die is attached to a surface of the first mold compound in the trench.

### BRIEF DESCRIPTION OF THE DRAWINGS

FIG. 1 is a plan view of a lead frame strip defining multiple substrates formed in accordance with example arrangements.

FIG. 2 is a partial cut-out, perspective view of a packaged device in accordance with example arrangements.

FIG. 3 is a perspective view of a substrate with a first die and a second die thereon, in accordance with example arrangements.

FIGS. 4A-F are schematic, cross-sectional views of a process for forming a packaged device in accordance with some arrangements.

FIG. 5 is a flowchart of a method for forming a device in accordance with some arrangements.

FIG. 6 is a flowchart of a method for forming a device in accordance with some arrangements.

FIG. 7 is a bottom, perspective view of a quad-flat no-leads (“QFN”) packaged device in accordance with some arrangements.

### DETAILED DESCRIPTION

In example arrangements, the problem of providing electrical isolation between semiconductor devices mounted on a substrate is solved by providing a portion of the substrate with an insulating material arranged for mounting a first semiconductor device that is electrically isolated from a second semiconductor device mounted to another portion of the substrate.

In this description, the term “trench” is used. As used in this description, a trench is a portion of a substrate where material is removed to form an opening at one surface of the substrate and having a recessed portion into the substrate at the opening with a bottom of the substrate material, and having sides extending from the opening into the substrate to the bottom of the recess. A trench can have a rectangular or square opening or other shaped opening at the surface with sides extending into the substrate, the sides forming a periphery of the trench and a bottom contacting the sides in the recess; alternatively the trench can extend entirely across the substrate so that the trench includes an opening and a recess into the substrate material in the opening with two opposing sides contacting the bottom of the recess, the trench having two opposing ends that are open at the periphery of the substrate. In the arrangements, the trench is filled with a dielectric material to form a “filled trench.” As used in this description the term “filled trench” includes the trench and the dielectric material in the trench.

In a described example, a packaged device includes a substrate with a first surface and an opposing second surface. The substrate includes a die pad having a trench formed therein and a die mounting area spaced from the trench. The trench extends partially into the die pad. The substrate further includes a first plurality of leads, and a second plurality of leads, with the second plurality of leads being spaced from, and electrically isolated from, the die pad. The packaged device further includes a first mold compound in the trench to form a filled trench and the first mold compound in the space between the second plurality of leads and the die pad, such that the first mold compound has a surface coplanar with a first surface of the die pad. A first die is attached to the die mounting area of the die pad and a second die is attached to the first mold compound in the filled trench, such that the first mold compound in the filled trench electrically isolates the second die from the first die. The packaged device further includes electrical connections between the first die and the second die, the first die and the first plurality of leads, and the second die and the second plurality of leads. A second mold compound covers the first die, the second die, and at least portions of the substrate.

In another described arrangement, a method includes attaching a first die to a first surface of a substrate, where the substrate comprises the first surface and an opposing second surface, attaching a second die to a first mold compound in a filled trench extending into the first surface of the substrate, electrically connecting the first die to the second die, the first die to the substrate, and the second die to the substrate, and covering the first die, the second die, the first mold compound and at least a portion of the substrate with a second mold compound.

In another described arrangement, a method includes forming a trench in a substrate, where the substrate comprises a die pad and leads, inserting a first mold compound into the trench, and inserting the first mold compound between the die pad and the leads. The method further includes attaching a first die to a die mounting area, where the die mounting area and the trench are on the die pad and where the die mounting area is spaced from the trench and attaching a second die to a surface of the first mold compound in the trench. The method further includes electrically connecting the first die to the second die, the first die to the substrate, and the second die to the substrate, and covering the first die, the second die, at least a portion of the substrate and the first mold compound with a second mold compound.

Some types of semiconductor packaging may co-package a first die with a second die, where the arrangement benefits from one of the dies being electrically isolated from the other die. In accordance with some arrangements, a first die may be a field-affect transistor (“FET”) die and a second die may be a driver or controller die, both of which are mounted on a first surface of a conductive substrate or lead frame. Both the FET die and the driver die may be attached to the substrate using a die attach, with the FET die attached by conductive die attach and the driver die attached using a nonconductive die attach. In a non-limiting illustrative arrangement, the driver die may be biased at a different potential than a ground coupled to the FET die and the system benefits from the driver die being electrically isolated from the FET die. Other arrangements should be appreciated in which the driver die may benefit from being isolated from the FET die. However, the nonconductive die attach used to attach the driver die to the substrate may not be sufficient to prevent leakage failures due to electro-migration and dendrite formation. Thus it may be beneficial to provide other or additional arrangements for isolating one die from the other die in a package, such as the driver die from the FET die.

In this description, the term “half etch” is used for a partial etch of the substrate. The term “half-etch” includes partial etches that extend half way, or more than or less than half way, through the thickness of the substrate. The half etch or partial etch may be achieved using a “half-etch process.” As used herein, in the half-etch process, part of the total thickness of the substrate is removed by etching, leaving a thinner portion as part of the finished substrate. In some half etch processes, partial etches are performed starting from the two opposing sides of the substrate, leaving two layers, one starting at the first surface and extending partway into the thickness of the substrate; while the second layer may start at the opposing second surface and extend partway into the thickness of the substrate. In some arrangements, the first layer and the second layer overlap such that the partial etches in the two layers may meet to form an opening that extends entirely through the substrate between the two opposing sides.

In this description, the term “die pad” refers generally to an area of the substrate configured to allow semiconductor dies to be mounted thereto.

Corresponding numerals and symbols in the different figures generally refer to corresponding parts unless otherwise indicated. The figures are not necessarily drawn to scale. Elements may be described as “encapsulated” herein. When a package is formed using mold compound, the packaged integrated circuit is referred to as “encapsulated” and the process for molding may be referred to as “encapsulation.” As used herein, when a die mounted to a substrate is described as encapsulated, portions of the substrate remain exposed to form leads or terminals for the packaged device, even though it is described as “encapsulated” or it is described as being formed by “encapsulation.” Elements are described herein as “coupled.” When an element is coupled to another element, it can be directly connected, or it can be connected through intervening elements, elements connected through intervening elements are also coupled to one another as meant herein.

The term “semiconductor device” as used herein means devices formed on a semiconductor substrate. The semiconductor substrate can be a silicon wafer. Additional semiconductor substrate materials useful with the arrangements include other semiconductor wafers, such as gallium arsenide, gallium nitride, indium, indium phosphide, gallium phosphide, germanium, and silicon germanium. Silicon on insulator (SOI) substrates, epitaxial semiconductor layers on other materials, such as SiGe layers, and other layers of semiconductor material can be used. The semiconductor devices can be discrete devices such as field effect transistors (FETs), bipolar junction transistors (BJT's), sensors, LEDs, bulk acoustic wave devices (BAW devices), photosensors, and analog devices. In addition, the term “semiconductor devices” includes integrated circuit (IC) devices with many hundreds, thousands or more devices integrated to form a single IC. The semiconductor devices are fabricated using semiconductor processes to form multiple identical devices on a substrate, and once processing reaches a certain stage, the identical devices are separated from the substrate into individual semiconductor devices referred to as dies. A die is one of the multiple semiconductor devices formed on the substrate, and the process for separating the individual dies from one another is referred to as “singulation.”

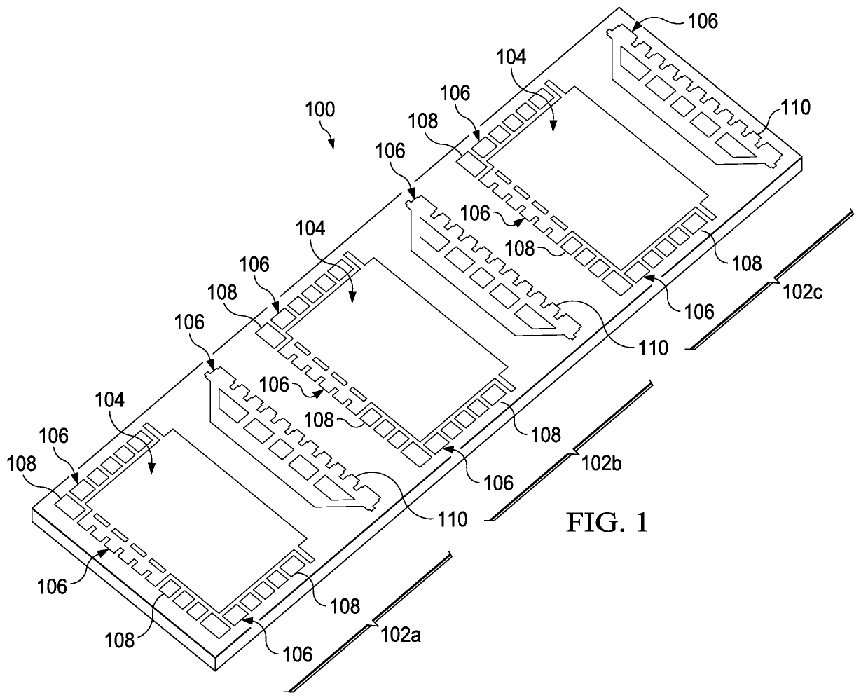

FIG. 1 is a top plan view of a lead frame strip 100 defining multiple substrates 102a, 102b and 102c (collectively referred to as “substrates 102” herein), which may also be referred to as lead frames. Each of the substrates 102 includes a die pad 104 and a plurality of leads 106. In some aspects, the plurality of leads 106 include a first plurality of leads 108 and a second plurality of leads 110, such that the second plurality of leads 110 are isolation leads that are spaced from and electrically isolated from the first plurality of leads 108.

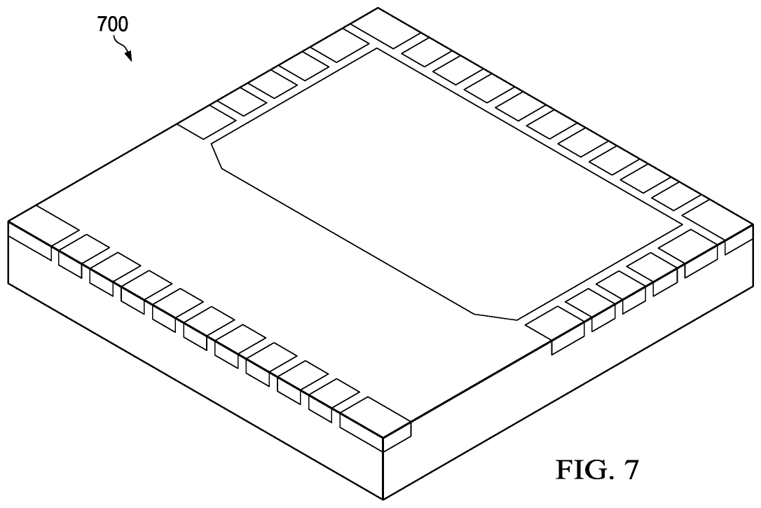

The lead frame strip 100 and each of the substrates 102 may be formed from a conductive metal material, such as copper, brass, stainless steel, or Alloy-42 (a nickel iron alloy) and may be formed through the use of either a chemical etching or mechanical stamping process. The lead frame strip may be coated with thin platings to enhance solderability or to reduce corrosion or prevent tarnishing. Nickel, silver, palladium, gold and combinations of these can be used for the platings. As is further described hereinbelow, the lead frame strip 100 will eventually be subjected to a singulation process to separate each one of the substrates 102 from each other to form individual packaged devices. FIG. 7 illustrates in one example a quad-flat no-leads (“QFN”) packaged device 700 described in more detail hereinbelow.

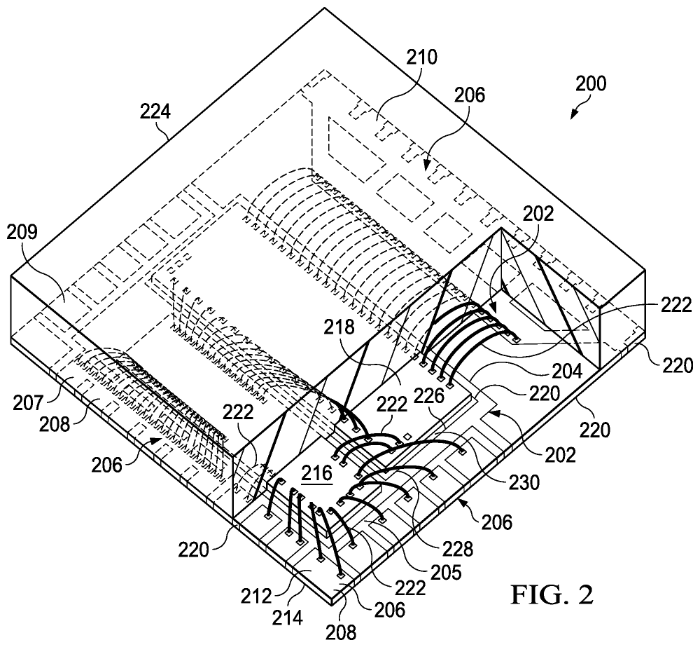

FIG. 2 is a partial cut-out, perspective view of a packaged device 200 in accordance with example arrangements. In FIG. 2, the reference labels used for similar elements are similar to those used in FIG. 1, for clarity. For example, substrate 202 corresponds to the substrate 102 in FIG. 1. In some aspects, the packaged device 200 may be a QFN packaged device, which may be similar to the QFN packaged device 700 illustrated in FIG. 7.

The packaged device 200 includes a substrate 202, which may be a lead frame. In alternative arrangements, the substrate 202 may be a molded interconnect substrate (MIS), a pre-molded lead frame (PMLF), or another conductive substrate or conductive lead frame. Substrate 202 has a die pad 204 and a plurality of leads 206. The die pad includes a die mounting area 205. The plurality of leads 206 includes a first plurality of leads 208 and a second plurality of leads 210, such that the second plurality of leads 210 are isolation leads that are spaced from and electrically isolated from the first plurality of leads 208. The first plurality of leads 208 may include both control pins 207 and source/ground pins 209. The second plurality of leads 210 may be a high voltage drain lead. The substrate 202 includes a first surface 212, which may be referred to as a top surface as the substrate 202 is oriented in FIG. 2, and an opposing, second surface 214, which may be referred to as a bottom surface as oriented in FIG. 2. The substrate 202 further includes a trench 226 formed into the first surface 212 of the substrate 202. The trench 226 is spaced from the die mounting area 205. The trench 226 may be a “half etch” or partial etch, which may be formed using a “half etch process.” In the half-etch process, part of the total thickness of the substrate is removed by etching, leaving a thinner portion as part of the finished substrate. In some half etch processes, partial etches are performed starting from the two opposing sides of the substrate, leaving two layers, one starting at the first surface and extending partway into the thickness of the substrate; while the second layer may start at the opposing second surface and extend partway into the thickness of the substrate.

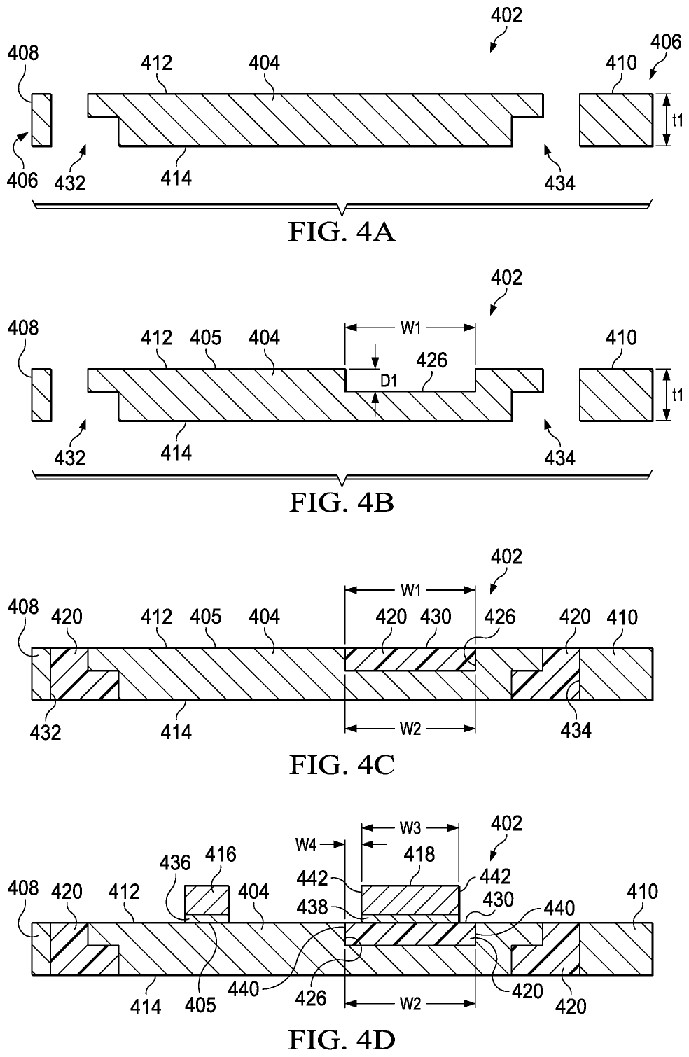

The lead frame used as the substrate in FIG. 2 includes mold compound as is further described hereinbelow. When lead frames are provided from a manufacturer including mold compound spacing portions of the lead frame, the lead frame can be referred to as a “pre-molded lead frame” or a “PMLF.” In the arrangements, a PMLF can be used to provide the substrate 202, alternatively, the mold compound spacing the portions of the lead frame can be applied prior to packaging a device by a lead frame user. In the example of FIG. 2, the trench 226 is formed in the die pad 204 portion of the substrate 202. A portion of a perimeter 228 of the trench 226 is shown in FIG. 2. Although not visible in the arrangement illustrated in FIG. 2, the trench 226 extends into the substrate 202 from the first surface 212 of the substrate 202. For reference, the arrangements illustrated in FIGS. 4B-4F below, show an example arrangement of a trench 426 extending into substrate 402 from a first surface 412 of the substrate 402.

Still referring to FIG. 2, a first mold compound 220 fills the trench 226 such that the first mold compound 220 has a first surface 230, which may be referred to as a top surface, that, in some aspects, is coplanar or flush with the first surface 212 of the substrate 202, so that trench 226 is a filled trench. When elements are referred to as being coplanar or flush as used herein, the elements are subject to manufacturing variations and tolerances and may not be perfectly coplanar or flush. In some aspects, the first mold compound 220 may be referred to as a premold because the first mold compound 220 may be applied to portions of the substrate 202, such as between the die pad 204 and the plurality of leads 206 and filling the trench 226, prior to other components being built upon the substrate 202, e.g., transistors, dies, and the like. In some aspects, the first mold compound 220 may be a dielectric or similar insulating material. Resin, epoxy resin, and polyimide are useful mold compounds. Mold compound can be supplied as a liquid or can be solid at room temperature. If a solid, the mold compound is heated prior to being injected into a mold. Mold compound for semiconductor devices can include fillers. The fillers can increase thermal performance by increasing thermal conductivity, provide additional mechanical strength, and reduce cost of the mold compound.

The packaged device 200 further includes a first die 216 and a second die 218 that are attached to the first surface 212 of the substrate 202 on the die pad 204. The dies can be any semiconductor devices, including discrete devices such as power transistors, inductors, capacitors, sensors, photocells, or resistors either singly or in multiple arrays, and can include integrated circuitry having several or even thousands of transistors coupled to perform a particular function. Example power transistors include power FET devices. Example integrated circuits include switching controllers for controlling power FETs in power supplies and power conversion applications, gate driver devices for power FETs, as well as analog to digital converters and processors. The first die 216 is attached to the die mounting area 205. The second die 218 is attached to the first mold compound 220 that fills the filled trench 226 portion of the substrate 202. The perimeter 228 of the filled trench 226 extends beyond an outer perimeter of the second die 218 so that the first mold compound 220 extends laterally beyond an outer perimeter of the second die 218. The first mold compound 220 electrically isolates the second die 218 from the first die 216. In some aspects the second die 218 is a driver or controller die and the first die 216 is a transistor die, such as a field-effect transistor (“FET”). The FET may be a lateral FET or a vertical FET. Wire bonds 222 connect the first die 216 and the second die 218, the first die 216 and the substrate 202, and the second die 218 and the substrate 202. In some arrangements, the wire bonds 222 connect the first die 216 and the second die 218, the first die 216 and the first plurality of leads 208, and the second die 218 to the second plurality of leads 210.

A second mold compound 224 covers at least portions of the first die 216, the second die 218, and the substrate 202. The second mold compound 224 may be referred to as an “overmold” because the second mold compound 224 may be applied to portions of the substrate 202 and at least partially cover elements added to the substrate 202, such as the first die 216 and the second die 218, after the components have been added or built upon the substrate 202. In some aspects, the second mold compound 224 may be a dielectric or similar insulating material. In some additional aspects, the first mold compound 220 and the second mold compound 224 are formed of different materials. In alternative aspects, the first mold compound and the second mold compound can be of same or similar materials. The second mold compound is coterminous with the first mold compound, such that a surface of the second mold compound shares a surface with a surface of the first mold compound.

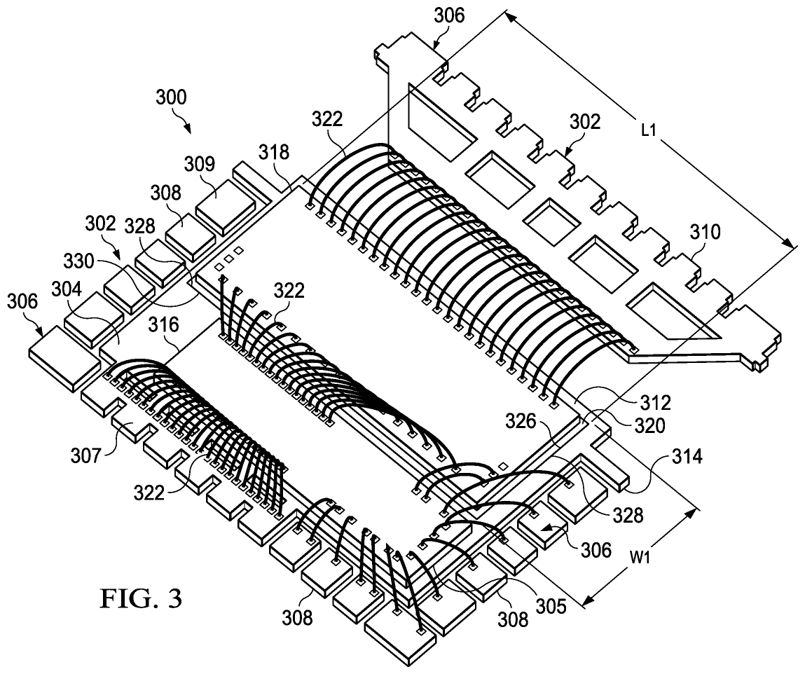

FIG. 3 is a perspective view of a portion of packaged device 300 having a substrate 302 with a first die 316 and a second die 318 positioned thereon. The packaged device 300 has a similar arrangement as the packaged device 200 illustrated in FIG. 2, except the package device 300 is illustrated without a mold compound covering portions of the substrate 302, such as the first die 316 and the second die 318. Like numerals may be used to refer to like elements for ease of understanding, e.g., substrate 202 illustrated in FIG. 2 and substrate 302 illustrated in FIG. 3. In some aspects, the package device 300 may be a QFN packaged device.

The substrate 302, which may also be referred to as a lead frame, has a die pad 304 and a plurality of leads 306. The plurality of leads 306 includes a first plurality of leads 308 and a second plurality of leads 310, such that the second plurality of leads 310 are isolation leads that are spaced from and electrically isolated from the first plurality of leads 308. The first plurality of leads 308 may include both control pins 307 and source/ground pins 309. The second plurality of leads 310 may be a high voltage drain lead. The substrate 302 includes a first surface 312, which may be referred to as a top surface, and an opposing, second surface 314, which may be referred to as a bottom surface. The substrate 302 further includes a half etch or trench 326 formed into the first surface 312 of the substrate 302. In particular, the trench 326 is formed in the die pad 304 portion of the substrate 302 and is spaced apart from a die mounting area 305 of the die pad 304. The trench 326 includes an outer perimeter 328. In an example arrangement, the trench 326 has a length L1 and a width W1, such that the length L1 is greater than the width W1. Although not visible in the arrangement as illustrated in FIG. 3, the trench 326 extends into the substrate 302 from the first surface 312 of the substrate 302. For reference, the arrangements illustrated in FIGS. 4B-4F below shows an illustrative arrangement of the trench 426 extending into the substrate 402 from the first surface 412 of the substrate 402.

Still referring to FIG. 3, a first mold compound 320 fills the trench 326 such that the first mold compound 320 has a first surface 330, which may be referred to as a top surface as oriented in FIG. 3, that, in some aspects, is coplanar or flush with the first surface 312 of the substrate 302. The trench 326 with the first mold compound forms a filled trench. The length and the width of the first mold compound 320 that fills the filled trench 326 is the same as the length L1 and the width W1 of the trench 326. In some aspects, the first mold compound 320 may be positioned between openings in the substrate 302, such as between the die pad 304 and the plurality of leads 306 and may be referred to as a premold for similar reasons as described hereinabove with respect to the first mold compound 220 of FIG. 2. In some aspects, the first mold compound 320 may be a dielectric or similar insulating material.

The packaged device 300 further includes the first die 316 attached to the first surface 312 of the substrate 302 on the die pad 304. The second die 318 is attached to the first mold compound 320 portion of filled trench 326. The perimeter 328 of the filled trench 326 extends beyond an outer perimeter of the second die 318 so that the first mold compound 320 extends laterally beyond an outer perimeter of the second die 318. In some aspects, the outer perimeter 328 of the filled trench 326 extends beyond the outer perimeter of the second die 318 by approximately 100 μm. In some additional aspects, the outer perimeter 328 of the filled trench 326 may extend beyond the outer perimeter of the second die 318 by between 10 and 120 μm. The first mold compound 320 in the filled trench 326 electrically isolates the second die 318 from the first die 316. In some aspects the second die 318 is a driver or controller die and the first die 316 is a transistor die, such as a lateral field-effect transistor (“FET”). The first die and the second die 316, 318 can be any semiconductor devices including discrete transistors, passives such as inductors, capacitors, resistors either singly or in arrays, and including integrated circuitry such as gate drivers and controllers for power FETs, microprocessors, digital signal processors, mixed signal processors, analog to digital converters, and microcontrollers. Electrical connections 322 electrically connect the first die 316 and the second die 318, the first die 316 and the substrate 302, and the second die 318 and the substrate 302. In some arrangements, the electrical bonds 322 connect the first die 316 and the second die 318, the first die 316 and the first plurality of leads 308, and the second die 318 to the second plurality of leads 310. In yet some arrangements, the electrical connections 322 are wire bonds. In additional arrangements, the electrical connections 322 can be made by ribbon bonds. In further arrangements, the first die 316 can be connected to leads on the substrate using “flip-chip” bonding, where conductive posts formed on bond pads on the die are connected to the substrate using solder on the ends of the posts. The second die 318 is mounted to the insulating mold compound 320 in the filled trench 326, however, and so flip chip bonding is not appropriate for the second die.

A second mold compound (not shown for simplicity) that is similar to the second mold compound 224 illustrated in FIG. 2 covers at least portions of the first die 316, the second die 318, and the substrate 302. In some aspects, the second mold compound may be referred to as an overmold for similar reasons as described hereinabove with respect to the second mold compound 224 of FIG. 2. In some aspects, the second mold compound may be a dielectric or similar insulating material. In additional aspects, the first mold compound 320 and the second mold compound are formed of different materials. In alternative aspects, the first and the second mold compound can be of the same material.

FIGS. 4A-F (collectively referred to as “FIG. 4” herein) are cross-sectional views of the results for steps of a process for forming a packaged device 400 (FIG. 4F) in accordance with some arrangements. In some aspects, the packaged device 400 may be a QFN packaged device, which may be similar to the QFN packaged device 700 illustrated in FIG. 7 and described in more detail below.

FIG. 4A illustrates a substrate 402. In this example the substrate is shown as a lead frame. The substrate 402 has a die pad 404 and a plurality of leads 406. In this example the plurality of leads 406 include a first plurality of leads 408 and a second plurality of leads 410, such that the second plurality of leads 410 are isolation leads that are electrically isolated from the first plurality of leads 408. The substrate 402 includes a first surface 412, which may be referred to as a top surface as oriented in FIG. 4, and an opposing, second surface 414, which may be referred to as a bottom surface as the substrate is oriented in FIG. 4. The substrate 402 has a thickness t1 between the first and second surfaces 412, 414. In an example the thickness t1 of the substrate 402 may be 200 μm. Other thicknesses are contemplated in additional aspects. The substrate 402 further includes a first gap or space 432 between the die pad 404 and the first plurality of leads 408 and a second gap or space 434 between the die pad 404 and the second plurality of leads 410.

FIG. 4B illustrates a trench 426 formed in the substrate 402 and, in particular, in the die pad 404 portion of the substrate 402. The trench 426 is spaced apart from a die mounting area 405 of the die pad 404. The trench 426 may be formed by a half etch process as defined above. The trench 426 includes a recess that extends into the substrate 402 from the first surface 412 of the substrate 402. The trench 426 has a width W1, a length (not shown but similar to the length L1 of the trench 326 illustrated in FIG. 3), and the recess has a depth D1 that extends into the substrate 402 from the first surface 412 to a recess bottom. In some arrangements, the width W1 of the trench 426 is between 1000 and 1500 microns, and the depth D1 is between 1 and 120 μm. In yet some arrangements, the depth D1 is between 80 and 120 μm or between 30 and 70% of the substrate thickness t1. The width W1 and the depth D1 depends on the size of a second die 418 (illustrated in FIG. 4D) and which will be explained in more detail below.

FIG. 4C illustrates the substrate 402 with a first mold compound 420 positioned in the gaps 432, 434 and in the trench to form a filled trench 426. In some aspects, the first mold compound 420 may be referred to as a premold because the first mold compound 420 may be applied to portions of the substrate 402 prior to other components being built upon the substrate 402, e.g., transistors, dies, and the like. In some aspects, the first mold compound 420 may be a dielectric or similar nonconductive, insulating material. The first mold compound 420 fills the trench 426 such that the first mold compound 420 has a first surface 430, which may be referred to as a top surface, that, in some aspects, is coplanar or flush with the first surface 412 of the substrate 402. The first mold compound 420 has a width W2 that is the same as the width W1 of the trench 426, e.g., between 1000 and 1500 microns.

FIG. 4D illustrates a first die 416 attached to the first surface 412 of the substrate 402 using a first die attach 436 and a second die 418 attached to the first surface 430 of the portion of the first mold compound 420 in the filled trench 426 using a second die attach 438. In some aspects, the first die attach 436 is a conductive die attach and the second die attach 438 is a nonconductive die attach. In yet some aspects, the first die attach 436 is a solder material. The second die attach 438 may be an adhesive, tape or epoxy.

The second die 418 has a width W3 that is less than the width W2 of the portion of the first mold compound 420 in the filled trench 426. In some aspects, the width W3 may be between 1000 and 1200 μm. Although not explicitly shown, the outer perimeter of the trench 426 and the portion of the first mold compound 420 that fills the filled trench 426 extends laterally beyond an outer perimeter of the second die 418. For example, sidewalls 440 of the portion of the first mold compound 420 in the filled trench 426 extend laterally away from sidewalls 442 of the second die 418 to a width W4. The distance between the outer perimeter of the first mold compound 420 that fills the filled trench 426 and, correspondingly, the width W4 between the sidewalls 440 of the first mold compound 420 and the sidewalls 442 of the sidewalls of the second die 418 provides electrical isolation between the second die 418 and the first die 416. In some aspects the second die 418 is a driver or controller die and the first die 416 is a transistor die, such as a lateral field-effect transistor (“FET”).

FIG. 4E illustrates electrical bonds 422 that connect the first die 416 and the second die 418, the first die 416 and the substrate 402, and the second die 418 and the substrate 402. In some arrangements, the electrical bonds 422 connect the first die 416 and the second die 418, the first die 416 and the first plurality of leads 408, and the second die 418 to the second plurality of leads 410.

FIG. 4F illustrates a second mold compound 424 that covers at least portions of the first die 416, the second die 418, and the substrate 402. In some aspects, the second mold compound 424 may be referred to as an “overmold” because the second mold compound 424 may be applied to portions of the substrate 402 and at least partially cover elements added to the substrate 402, such as the first die 416 and the second die 418, after the components have been added or built upon the substrate 402. In some aspects, the second mold compound 424 may be a dielectric or similar insulating material. In yet some aspects, the first mold compound 420 and the second mold compound 424 are formed of different materials.

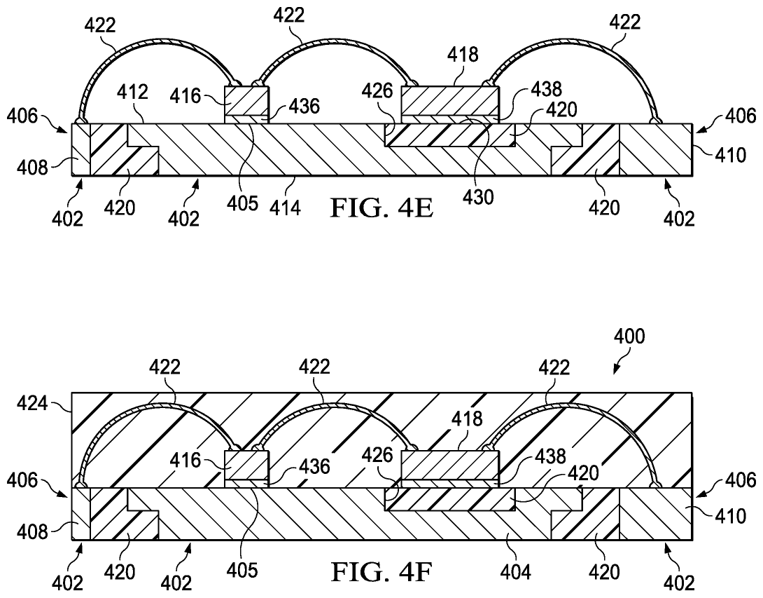

FIG. 5 is a flowchart of a method 500 for forming a packaged device in accordance with some arrangements. In describing the steps disclosed in the flowchart of FIG. 5, FIGS. 4A-F will be referred to and the elements illustrated therein. Step 502 of FIG. 5 corresponds with FIGS. 4A-D. FIGS. 4A-D illustrate step 502 and 504 of FIG. 5 in attaching the first die 416 to the first surface 412 of the substrate 402, the substrate 402 comprising the first surface 412 and an opposing second surface 414 and attaching the second die 418 to the first mold compound 420 in the filled trench 426 extending into the first surface 412 of the substrate 402.

In step 506 and illustrated in FIG. 4E, the first die 416 is electrically connected to the second die 418, the first die 416 is electrically connected to the first plurality of leads 408, and the second die 418 is electrically connected to the second plurality of leads 410.

In step 508 and illustrated in FIG. 4F, at least a portion of the first die 416, the second die 418, the first mold compound 420 and the substrate 402 is covered with the second mold compound 424.

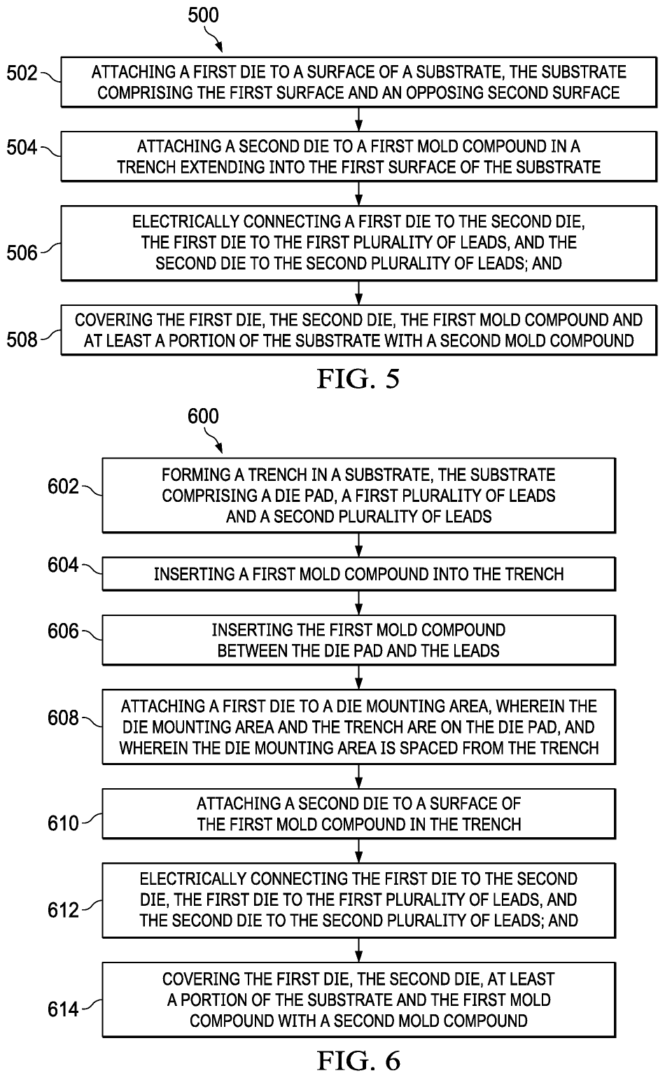

FIG. 6 is a flowchart of a method 600 for forming a packaged device in accordance with some arrangements. In describing the steps disclosed in the flowchart of FIG. 6, FIGS. 4A-F will be referred to and the elements illustrated therein. Step 602 of FIG. 6 corresponds with FIGS. 4A-B. FIGS. 4A-B illustrate step 602 of FIG. 6 in forming a trench 426 in the substrate 402, the substrate comprising the die pad 404 and leads 406, the leads 406 including the first plurality of leads 408 and the second plurality of leads 410.

In step 604 and 606 of FIG. 6, illustrated in FIG. 4C, the first mold compound 420 is inserted into the trench 426 to form a filled trench and is placed between the die pad 404 and the leads 406, wherein the leads 406 include the first plurality of leads 408 and the second plurality of leads 410.

In step 608 and 610 of FIG. 6, illustrated in FIG. 4D, the first die 416 is attached to the die mounting area 405, wherein the die mounting area 405 and the filled trench 426 are on the die pad 404, wherein the die mounting area 405 is spaced from the filled trench 426, and the second die 418 is attached to a surface 430 of the first mold compound 420 in the filled trench 426.

In step 612 and illustrated in FIG. 4E the first die 416 is electrically connected to the second die 418, the first die 416 is electrically connected to the first plurality of leads 408, and the second die 418 is electrically connected to the second plurality of leads 410.

In step 614 and illustrated in FIG. 4F the first die 416, the second die 418, at least a portion of the substrate 402 and the first mold compound 420 are covered with the second mold compound 424.

FIG. 7 is a bottom, perspective view of a quad-flat no-leads (“QFN”) packaged device 700 in accordance with some arrangements. The packaged device 700 may implement any of the above-mentioned arrangements described in connection to FIGS. 1-6.

Modifications are possible in the described embodiments, and other embodiments are possible, within the scope of the claims.

1. An apparatus comprising:
a substrate comprising:
a first surface and an opposing second surface;
a trench extending into the substrate from the first surface;
a die mounting area adjacent to the trench;
a first plurality of leads;
a second plurality of leads, wherein the second plurality of leads are spaced from the trench to electrically isolate the second plurality of leads;
a first mold compound filling the trench to form a filled trench and in the space between the filled trench and the second plurality of leads;
a first die attached to the first surface of the substrate in the die mounting area, and
electrically connected to at least one of the first plurality of leads; and
a second die attached to a surface of the first mold compound in the filled trench.

2. The apparatus of claim 1, wherein the trench is a partial etch forming a recess that extends partially into the substrate and having a bottom of the substrate.

3. The apparatus of claim 1, wherein the first die is attached to the die mounting area of the substrate by a conductive die attach.

4. The apparatus of claim 1, wherein the second die is attached to the first mold compound in the filled trench by an adhesive.

5. The apparatus of claim 1, wherein the filled trench has a first width greater than a second width of the second die.

6. The apparatus of claim 1, wherein the first surface of the substrate and a surface of the first mold compound are substantially coplanar.

7. The apparatus of claim 1, wherein a depth of the first mold compound is between 1 and 100 microns, wherein a width of the first mold compound is wider than a width of the second die, and wherein the first surface of the substrate and the surface of the first mold compound is substantially coplanar.

8. The apparatus of claim 1 further comprising:
electrical connections between the first die and the second die, and the second die and at least one of the second plurality of leads; and
a second mold compound over at least a portion of the substrate.

9. The apparatus of claim 8, wherein the second mold compound and the first mold compound are of the same material.

10. A packaged device, comprising:
a substrate having a first surface and an opposing second surface, the substrate comprising:
a die pad having a trench formed therein and a die mounting area spaced from the trench, and wherein the trench extends partially into the die pad;
a first plurality of leads, and a second plurality of leads, the second plurality of leads being spaced from, and electrically isolated from, the die pad;
a first mold compound in the trench to form a filled trench and in the space between the second plurality of leads and the die pad, the first mold compound having a surface coplanar with a first surface of the die pad;
a first die attached to the die mounting area of the die pad;
a second die attached to the first mold compound in the filled trench, wherein the first mold compound in the filled trench electrically isolates the second die from the first die;
electrical connections between the first die and the second die, the first die and the first plurality of leads, and the second die and the second plurality of leads; and
a second mold compound covering the first die, the second die, and at least portions of the substrate.

11. The packaged device of claim 10, wherein a surface of the second mold compound is coterminous with a surface of the first mold compound.

12. The packaged device of claim 10, wherein the space between the second plurality of leads and the die pad is at least 100 microns.

13. The packaged device of claim 10, wherein an outer perimeter of the filled trench extends beyond an outer perimeter of the second die.

14. The packaged device of claim 13, wherein a distance between the outer perimeter of the filled trench and the outer perimeter of the second die is at least 100 microns.

15. The packaged device of claim 10, wherein the substrate has a height of approximately 200 microns between the first surface and the second surface.

16. The packaged device of claim 10, wherein a depth of the trench is approximately 80 to 100 microns.

17. A method comprising:
attaching a first die to a first surface of a substrate, the substrate comprising the first surface and an opposing second surface, a first plurality of leads and a second plurality of leads;
attaching a second die to a first mold compound in a filled trench, the trench including a recess extending into the first surface of the substrate and having a bottom within the substrate;
electrically connecting the first die to the second die, the first die to the first plurality of leads, and the second die to the second plurality of leads; and
covering the first die, the second die, the first mold compound and at least a portion of the substrate with a second mold compound.

18. The method of claim 17, wherein the trench extends into the substrate, the substrate is a conductive lead frame, the substrate is a pre-molded lead frame with a die pad portion and leads spaced from one another by additional portions of the first mold compound that fills the filled trench.

19. The method of claim 17, wherein the first mold compound is a pre-mold that fills the trench prior to attaching the first die and the second die, and wherein the second mold compound is an overmold that is covers the first die, the second die and at least a portion of the substrate after attaching the first and second dies.

20. The method of claim 17, wherein the substrate is conductive, and wherein the second die is electrically isolated from the substrate by the first mold compound.

21. A method comprising:
forming a trench in a substrate having a recess extending into the substrate and having a bottom within the substrate, the substrate comprising a die pad, a first plurality of leads and a second plurality of leads;
inserting a first mold compound into the trench to form a filled trench;
inserting the first mold compound between the die pad and the leads;
attaching a first die to a die mounting area, wherein the die mounting area and the filled trench are on the die pad, and wherein the die mounting area is spaced from the filled trench;
attaching a second die to a surface of the first mold compound in the filled trench;
electrically connecting the first die to the second die, the first die to the first plurality of leads, and the second die to the second plurality of leads; and
covering the first die, the second die, at least a portion of the substrate and the first mold compound with a second mold compound.

22. The method of claim 21, wherein the trench extends partially through the substrate.

23. The method of claim 21, wherein the substrate is a conductive lead frame, and wherein the first mold compound electrically isolates the die pad from the leads.
